(19) United States
(12) Patent Application Publication
(10) Pub. No.: US 2025/0273431 A1
(43) Pub. Date: Aug. 28, 2025

(54) HYBRID DUAL FREQUENCY PLASMA METHOD AND APPARATUS FOR DEPOSITION IN PATTERNED FEATURES ON A SUBSTRATE

(71) Applicant: ASM IP Holding B.V., Almere (NL)

(72) Inventors: Musa Alaydrus, Helsinki (FI); Toshiaki Iijima, Tokyo (JP); Ryoko Yamada, Odawara-shi (JP); Hiroki Matsuda, Tokyo (JP); Jun Yoshikawa, Tokyo (JP); Agung Setiadi, Tokyo (JP); Jun Kawahara, Tokyo (JP); Annisa Noorhidayati, Tokyo (JP)

(21) Appl. No.: 19/059,551

(22) Filed: Feb. 21, 2025

Related U.S. Application Data
(60) Provisional application No. 63/557,727, filed on Feb. 26, 2024.

(51) Int. Cl. H01J 37/32; C23C 16/04; C23C 16/505

(52) U.S. Cl. CPC H01J 37/32146; C23C 16/04; C23C 16/505; H01J 2237/332

(57) ABSTRACT

A method for depositing a film in a feature on a substrate, includes forming a hybrid dual frequency plasma. Forming a hybrid dual frequency plasma includes forming a continuous plasma at a high and low RF frequency for a first time period and forming a pulsed plasma at a low RF frequency for a second time period to deposit a film into the feature on the substrate.

### CROSS-REFERENCE TO RELATED APPLICATIONS

This application claims priority to U.S. Provisional Patent Application Ser. No. 63/557,727 filed Feb. 26, 2024 titled HYBRID DUAL FREQUENCY PLASMA METHOD AND APPARATUS FOR DEPOSITION IN PATTERNED FEATURES ON A SUBSTRATE, the disclosure of which is hereby incorporated by reference in its entirety.

### FIELD

Embodiments are described that relate to a method for depositing a film in a gap on a substrate using a hybrid dual frequency plasma, as well as an apparatus for use of the hybrid dual frequency plasma.

### BACKGROUND

In processes for fabricating integrated circuits, it is often desirable to fill deep and complex patterned structures, such as trenches or recesses with high aspect ratios, with high quality films. However, it has become increasingly difficult to fill these deep and complex patterned structures with current deposition methods. Current methods may produce films with poor sidewall film quality or poor deposition into the bottom of deep structures. Therefore, there exists a need for methods capable of filling deep and complex patterned structures with high quality and/or conformal films.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Embodiments and examples described herein provide a substrate processing method and a substrate processing apparatus. Various examples of the substrate processing apparatus and substrate processing method employ use of a hybrid dual frequency plasma to produce films having improved conformality and quality. Additional aspects are set forth in part in the description which follows.

According to one or more embodiments, a method for depositing a film in a gap on a substrate is provided. An exemplary method includes providing a substrate, having a gap structure thereon, into a reaction chamber. At least one reactant may be supplied into the reaction chamber. In some embodiments, the method may further comprise supplying one or more precursors into the reaction chamber. In the reaction chamber, a hybrid dual frequency plasma cycle may be performed to deposit a film. The hybrid dual frequency plasma cycle may comprise forming a continuous plasma for a first time period and forming a pulsed plasma for a second time period. In some embodiments, the hybrid dual frequency plasma cycle may be repeated one or more times until the film reaches a predetermined thickness. In some embodiments, a first iteration of forming a pulsed plasma is performed at a different power, RF frequency, or duration than a second iteration of forming a pulsed plasma. In some embodiments, the method may optionally comprise performing a post-deposition treatment.

In some embodiments, the gap structure comprises a bottom and a sidewall. In some embodiments, the gap structure may have a depth greater than 160 nm or between about 110 nm and 300 nm. In some embodiments, a ratio of the thickness of the film deposited on the sidewall to the thickness of the film deposited on the bottom is between about 1 and about 5, or between about 2 and about 3.

In some embodiments, the at least one reactant is continuously supplied into the reaction chamber during the hybrid dual frequency plasma cycle. In some embodiments, the at least one reactant is continuously supplied throughout multiple hybrid dual frequency plasma cycles.

In some embodiments, the continuous plasma is formed by providing a continuous high RF power state and providing a continuous low RF power state. In some embodiments, the power of the continuous high RF power state is in the range of about 700 W to about 1000 W, or between about 700 to 1500 W. In some embodiments, the time period of the continuous plasma is in the range of about 4 s to about 14 s, or between about 2 seconds and 20 seconds.

In some embodiments, the pulsed plasma may be formed by pulsing a low RF power state. In some embodiments, the time period of the pulsed plasma is in the range of about 10 seconds to about 14 seconds. In some embodiments, the pulsed plasma pulses between an on state and an off state. In some embodiments, the low RF power state of the pulsed plasma may be in the range of about 20 W to about 100 W, or between about 20 W and about 500 W. In other embodiments, the low RF power state of the pulsed plasma pulses between at least a first power state and a second power state, wherein power delivered during the first power state is different from power delivered during the second power state. The power of the first power state may be in the range of about 60 W to about 100 W, or between 20 and about 100 W, and the power of the second power state may be in the range of about 20 W to about 60 W, or between about 20 and about 100 W.

In some embodiments, a ratio of the time period of the continuous plasma to the time period of the pulsed plasma is in the range of about 1 to about 4. In some embodiments, the RF on duty cycle % of the pulsed plasma is in the range of 25% to 75%. In some embodiments, the time period of the pulsed plasma is immediately subsequent to the time period of the continuous plasma. In some embodiments, there is an intervening time period between the time period of the continuous plasma and the time period of the pulsed plasma.

In some embodiments, a pressure in the reaction chamber during the hybrid dual frequency plasma cycle is less than 9 torr. In some embodiments, the pressure of the reaction chamber during the hybrid dual frequency plasma cycle is in the range of about 3 to about 9 torr, or in the range of about 7 to about 9 torr.

In some embodiments, the post-deposition treatment may include exposing the substrate to a plasma or species generated by a plasma. In some embodiments, the post-deposition plasma treatment includes generating a dual frequency plasma. In some embodiments, the dual frequency plasma is a nitrogen plasma (i.e., the plasma is generated using a nitrogen-containing gas and/or the plasma contains excited nitrogen species). In some embodiments, the dual frequency plasma includes providing a first RF power having a first RF frequency and a second RF power having a second frequency. In some embodiments, the first RF power is continuous during one or more process steps. In some embodiments, the second RF power is pulsed during one or more process steps. In some embodiments, the first RF frequency is greater than the second RF frequency. In some embodiments, the first frequency is a VHF frequency (e.g., greater than 27 MHz). In some embodiments, the second frequency is a low RF frequency (e.g., less than 1 MHz).

According to one or more embodiments, an apparatus capable of depositing films on a substrate is provided. The apparatus may include a reaction chamber, a gas distribution system for delivering gas phase reactants to the reaction chamber, a plasma generator for providing a continuous plasma and a pulsed plasma to the reaction chamber, and a controller operably connected to the gas distribution system and the plasma generator and comprising a program residing on non-transitory addressable storage medium. The controller may be configured to enact the steps of: introducing at least one reactant into the reaction chamber and performing a hybrid dual frequency plasma cycle, wherein the hybrid dual frequency plasma cycle comprises forming a continuous plasma for a first time period, and forming a pulsed plasma for a second time period and/or other methods or method steps as described herein.

### BRIEF DESCRIPTION OF THE DRAWINGS

FIG. 1A illustrates a method for deposition of a film according to one or more embodiments of the disclosure;

FIG. 1B illustrates a method of forming a hybrid dual frequency plasma cycle in accordance with one or more examples of the disclosure;

FIG. 2 illustrates a timing sequence suitable for use with a method for deposition of a film according to one or more embodiments of the disclosure;

FIG. 3 illustrates a structure according to the disclosure;

FIG. 4 illustrates an apparatus in accordance with exemplary embodiments of the disclosure.

FIG. 5 illustrates a timing sequence suitable for use with a post-deposition treatment according to one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Reference will now be made in detail to embodiments, which are illustrated in the accompanying drawings. In this regard, the examples may have different forms and should not be construed as being limited to the descriptions set forth herein.

As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments and is not intended to limit the disclosure. As used herein, the singular forms “a,” “an,” and “the” are intended to include the plural forms as well, unless the context clearly indicates otherwise. It will be further understood that the terms “includes,” “comprises,” “including,” and/or “comprising” used herein specify the presence of stated features, integers, steps, processes, members, components, and/or groups thereof, but do not preclude the presence or addition of one or more other features, integers, steps, processes, members, components, and/or groups thereof.

Where an (e.g., RF) plasma is used, a low RF frequency (LF) may be lower than 1 MHz, or between 430 kHz and 1 MHz, or between about 40 kHz and 800 kHz, a high RF frequency (HF) may be greater than 1 MHz, or between 13 and 100 MHz, or between about 13.56 MHz and 27 MHz, and a very high RF frequency (VHF) may be greater than 27 MHz, greater than 30 MHz, greater than 40 MHz, greater than 60 MHz, or between about 30 MHz and 5 GHz.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate. By way of examples, one or more features can have a width of about 10 nm to about 100 nm, a depth or height of about 30 nm to about 1,000 nm or greater than 160 nm, and/or an aspect ratio of about 1:1, 1:3, 1:10, 1:100, or more, or any ranges therebetween. In some examples, the one or more features may comprise a gap structure comprising a bottom and one or more sidewalls. In some examples, the one or more sidewalls may not be straight, such that the width of the gap structure is not uniform by the depth. In some examples, the one or more sidewalls may have a convex shape. In some examples, the one or more sidewalls may bulge below an opening of the gap structure. In some examples, the gap structure may have a neck at the opening of the gap structure.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous-or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “cyclic deposition process” can refer to a vapor deposition process in which deposition cycles, typically a plurality of consecutive deposition cycles, are conducted in a process chamber. Cyclic deposition processes can include cyclic plasma-enhanced chemical vapor deposition (CVD) and/or plasma-enhanced atomic layer deposition (ALD) processes. A cyclic deposition process can include one or more cycles that include plasma activation of a precursor, a reactant, and/or an inert gas in any combination.

In this disclosure, “continuously” can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

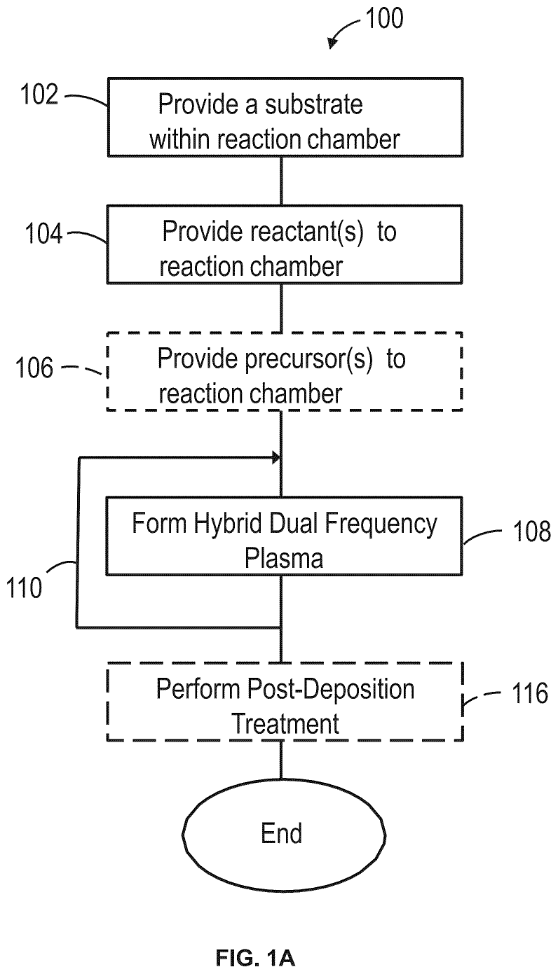

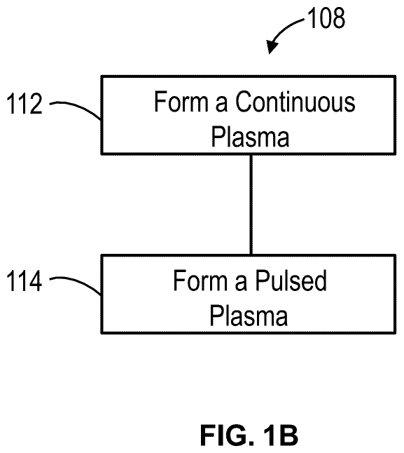

FIG. 1A illustrates a method of depositing a film into a gap on a substrate in accordance with exemplary embodiments of the disclosure. Method 100 includes the step of providing a substrate within a reaction chamber (step 102), providing one or more reactants to the reaction chamber (step 104), forming a hybrid dual frequency plasma to deposit a film on the substrate (step 108), and optionally performing a post-deposition treatment (step 112). Method 100 can also include a step of providing one or more precursors to the reaction chamber (step 106). As illustrated, method 100 can include repeating step 108 a number of times (loop 110) until the deposited film reaches a desired thickness.

During step 102, a substrate is provided into a reaction chamber. In accordance with examples of the disclosure, the reaction chamber can form part of a chemical vapor deposition reactor, such as a plasma-enhanced chemical vapor deposition (PECVD) reactor or plasma-enhanced atomic layer deposition (PEALD) reactor. Various steps of methods described herein can be performed within a single reaction chamber or can be performed in multiple reaction chambers, such as reaction chambers of a cluster tool.

During step 102, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be between about 300 and about 500° C. By way of examples, a pressure within a reaction chamber can be less than or equal to 100 torr, or less than or equal to 20 torr or, preferably, in the range of 7 torr to 9 torr.

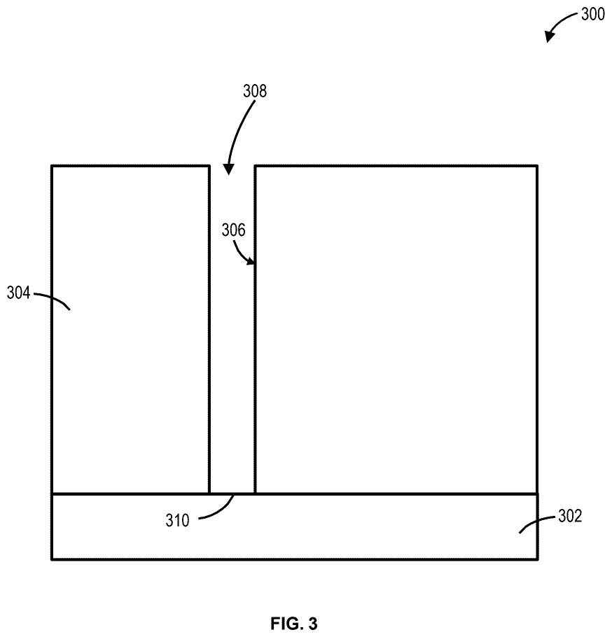

In accordance with particular examples of the disclosure, the substrate provided during step 102 includes one or more features, such as gaps or recesses. FIG. 3 illustrates a portion of a substrate 300 comprising a patterned feature 308. In the illustrated examples, substrate 300 includes bulk material 302 and a layer 304 formed thereon. In some cases, layer 304 can include insulating or dielectric material. Feature 308 may include a bottom 310 and a sidewall 306. In some cases, the feature may have a non-straight or non-vertical sidewall, such that the width of the feature varies by depth. In some cases, a feature, such as feature 308, may have a neck or may bow.

Turning back to FIG. 1A, during step 104, one or more reactants are provided to the reaction chamber. The one or more reactants can be flowed to the reaction chamber at the same time or overlapping in time with step 106 of providing one or more precursors to the reaction chamber. In this case, a CVD reaction can occur. In some cases, the one or more reactants and/or the one or more precursors can be pulsed to the reaction chamber for a cyclical process, such as a cyclical CVD or ALD process. In some cases, the one or more reactants can flow continuously through step 108 of forming a hybrid dual frequency plasma.

Exemplary reactants provided during step 104 include compounds including one or more of nitrogen and hydrogen. Additionally, a carrier and/or inert gas can be co-flowed during step 104. By way of example, the reactants can be or include an inert gas such as argon.

During step 106, one or more precursors may be supplied to the reaction chamber. The one or more precursors can be any suitable precursors suitable for forming a film. Exemplary precursors can include a compound comprising carbon and/or silicon. In some embodiments, the one or more precursors can be co-flowed into the reaction chamber along with the one or more reactants, in a separate step than step 104, or with an overlapping time period with step 104. By way of example, the precursors can be or include an inert gas, such as argon.

During step 108, a hybrid dual frequency plasma is formed. A temperature and pressure in the reaction chamber during step 108 may be the same as in step 102. As shown in FIG. 1B, step 108 includes sub-step 112 of forming a continuous plasma and a sub-step 114 of forming a pulsed plasma.

Sub-step 112 of forming a continuous plasma includes forming a plasma with a high RF power state component and a low RF power state component. A high RF frequency of the high RF power state component may be a frequency between about 1 MHz and about 200 MHz, in the range of about 13 MHz to 100 MHz, or in the range of about 13.56 MHz to about 27 MHz, or between about 13.56 MHz to 200 MHz. A power of the high RF power state may be in the range of about 400 W and about 2000 W, or about 700 W and about 1000 W, or about 500 and 1500 W. A low RF frequency of the low RF power state component may be a frequency about 430 kHz and about 1 MHz. A power of the low RF power state may be 500 W or less, or in the range of 20 W to 500 W, or between about 20 W to about 100 W.

Sub-step 114 of forming a pulsed plasma includes forming a plasma with a pulsed low RF power state component. A low RF frequency may be a frequency under 1 MHz, under 500 kHz, or about 250 to about 430 kHz. The pulsed low RF power state may be the same frequency as the low RF power state component of the continuous plasma of sub-step 112. During the sub-step 114, the low RF power state is pulsed. In some embodiments, a pulse can include a pulse on time and a pulse off time. The power of the low RF during the pulse on time may be 500 W or less, or in the range of 300 W to 500 W. The power or the low RF during the pulse on time may be the same as the power of the low RF power state of the continuous plasma of sub-step 112. The power of low RF during the pulse off time can be about 0 W. During sub-step 114, a pulse can be repeated one or more times. In some embodiments, a pulse can include a first low RF power state and a second low RF power state. The power of the low RF during the first low RF power state may be 500 W or less, in the range of 20 W and 100 W, or in the range of 60 W to 100 W. The power of the low RF during the second low RF power state may be 500 W or less, in the range of 20 W and 100 W, or in the range of 20 W to 60 W. The power or the low RF during the first low RF power state or the second low RF power state may be the same as the power of the low RF power state of the continuous plasma of sub-step 112. The power delivered during the first low RF power state is greater than the second low RF power state. In some embodiments, there is no high RF plasma power during sub-step 114, i.e. the pulsed plasma power of sub-step 114 only has a low RF power state component and no high RF power state component.

Not to be bound by theory, the high RF frequency plasma of the hybrid dual frequency plasma is thought to be able to generate a plasma, while the low frequency plasma is used to control the energy and distribution of the excited species and ions of the generated plasma. The pulsed plasma further helps control the angle and distribution of the excited species and ions of the generated plasma. Higher energy excited species and ions generated during the continuous plasma sub-step of the hybrid dual frequency plasma are more likely to penetrate into the depth of a gap or other narrow patterned feature on a substrate surface. Lower energy excited species and ions are more likely to have a broader radial distribution and be able to reach the sidewall of a gap or feature. The pulsed plasma allows for greater radial distribution and sidewall coverage. Further the pulsed plasma allows for excited species and ions to reach non-uniformities on a sidewall. Combining the continuous plasma and pulsed plasma steps allows for better control of distribution and energies of excited species and ions, and a more tailored deposition of a film in the gap or feature.

Turning again to FIG. 1A, as illustrated, method 100 can include repeating the step 108 of forming a hybrid dual frequency plasma a number of times (loop 110). Step 108 can be repeated a number of times until a desired thickness of a film is deposited on the gap structure. In some embodiments, a first iteration of forming a pulsed plasma is performed at a different power, RF frequency, or duration than a second iteration of forming a pulsed plasma. The power, RF frequency, or duration of the second iteration may be a power, RF frequency, or duration as disclosed.

Method 100 continues with optionally performing a post-deposition treatment 112. The post-deposition treatment 112 may comprise exposing the substrate to a plasma and/or to species generated by a plasma. In an embodiment, the plasma is generated in the reaction chamber. In some embodiments, the plasma comprises a nitrogen plasma (i.e., the plasma is generated using a nitrogen-containing gas and/or the plasma contains excited nitrogen species). By way of examples, the nitrogen-containing gas used to generate the nitrogen plasma can include one or more of nitrogen (N₂), ammonia, hydrazine, nitrogen dioxide, or nitrogen monoxide. In some embodiments, the nitrogen-containing gas further comprises one or more inert gases, such as helium and argon.

In some embodiments, the plasma formed during the post-deposition treatment 112 is a dual frequency plasma. Forming or generating the dual frequency plasma comprises (e.g., concurrently) providing a first RF power having a first RF frequency and a second RF power having a second frequency. In some embodiments, the first RF frequency is greater than the second RF frequency. In some embodiments, the first frequency is a VHF frequency (e.g., greater than 27 MHz, or greater than 30 MHz, or greater than 40 MHz, or greater than 60 MHz). In some embodiments, the second frequency is a low RF frequency (e.g., less than 1 MHz, or between about 40 kHz and about 800 kHz). In some embodiments, the first RF power is continuous during one or more process steps. In some embodiments, the second RF power is pulsed during one or more process steps. In such case, the plasma may be continuous. In some embodiments, a duty cycle of the second RF power (i.e., the percent of RF on-time in the total time of one cycle of RF on and RF off time) is 50% or less, or 30% or less, or 25% or less. In some embodiments, the dual frequency plasma is generated for a time period between about 10 seconds and about 600 seconds, or between about 30 seconds and about 300 seconds, or between 90 seconds and 240 seconds. In some embodiments, a power of the first RF power is greater than 800 W, or between about 800 W and about 1200 W, or between about 900W and 1000 W. In some embodiments, a power of the second RF power is between 1 W and 400 W, or between about 10 W and 200 W, or between about 20 W and about 50 W. The power levels can be for a 300 mm diameter substrate or similarly scaled for substrates of other dimensions. A pressure in the reaction chamber during the post-deposition treatment may be less than 50 Torr, or less than 20 Torr, or less than 10 Torr, or between about 1 Torr and 10 Torr.

The post-deposition treatment may improve the density of the deposited film. The dual frequency plasma of the post-deposition treatment may by anisotropic or have a broader distribution of angles of species in the plasma. Not to be bound by theory, one of the components of the dual frequency plasma (e.g., the continuous VHF RF power component) may be able to excited species and generate a plasma, while the other component (e.g., the pulsed low RF power component) may be able to tune the angle of excited species, tune the flux of excited species, and tune the energy of excited species reaching a sidewall in a feature or a gap. The dual frequency plasma may be able to improve the quality of a film on a sidewall of a feature or a gap by allowing species generated from the plasma into the gap or feature and onto the sidewall. The dual frequency nitrogen plasma of the post-deposition treatment may add nitrogen to the film, may increase Si—N bonding films comprising silicon, and may remove hydrogen from the film.

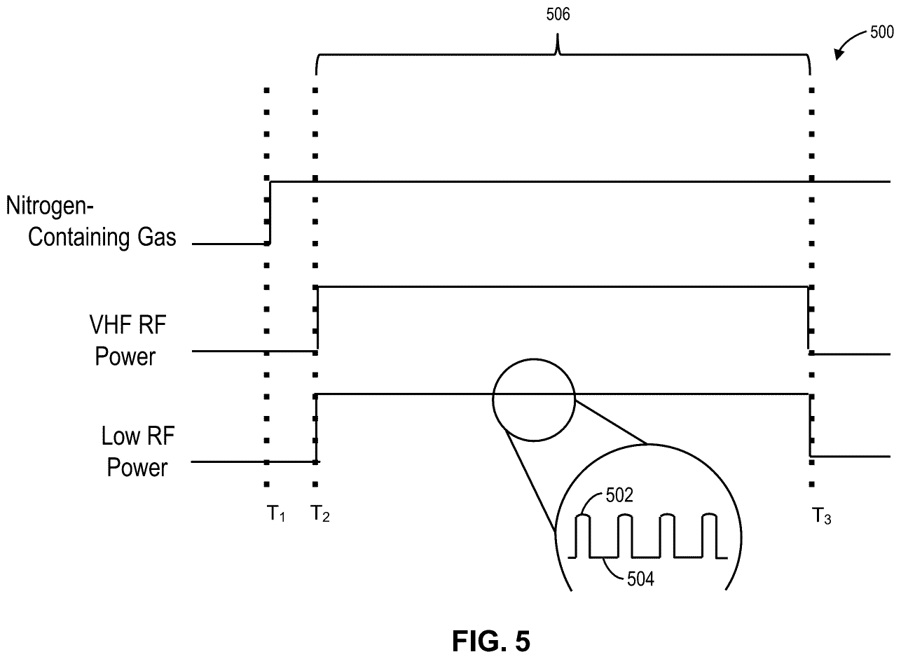

FIG. 5 illustrates a timing sequence suitable for a post deposition treatment in accordance with examples of the disclosure. As illustrated in FIG. 5, a nitrogen-containing gas may be provided to the rection chamber at T₁. Thereafter, at T₂, a plasma using VHF RF power and Low RF power is formed. The component of VHF RF power is continuous, while the component of Low RF power is pulsed as illustrated in the enlarged portion of FIG. 5. A pulse can include a pulse on time 202 and a pulse off time 204, which can be repeated during period 506. During the period 506, the plasma may have an RF duty cycle, or the percentage of the pulse on time 502 of a pulse (i.e. (pulse on time/(pulse on time+pulse off time))×100%). RF on duty cycle can be in the range of 50% or less, or 30% or less, or 25% or less, or between about 1% and 25%. The plasma is maintained throughout the duration of time period 506. At T₃, the power to form the plasma is reduced to extinguish the plasma.

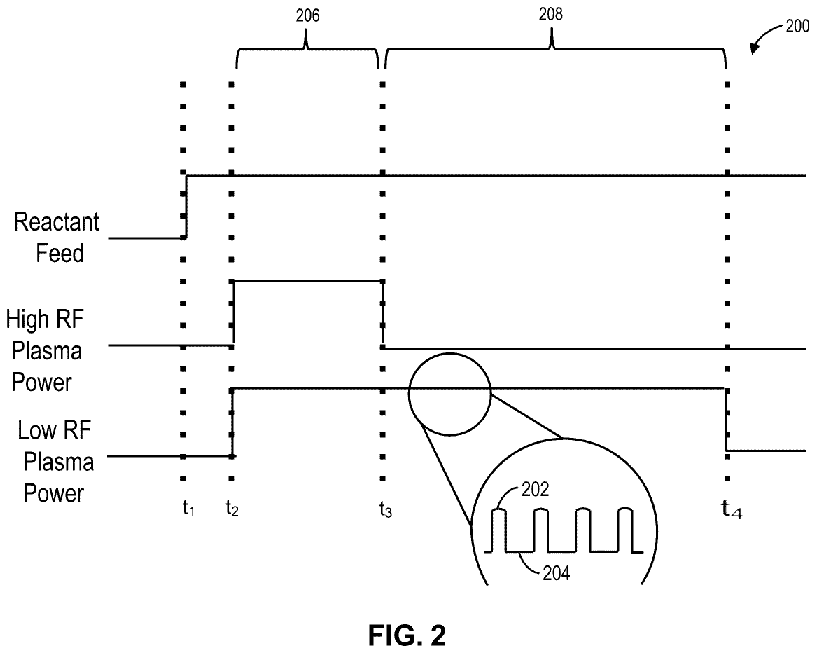

FIG. 2 illustrates a timing sequence suitable for a portion of the method 100 in accordance with examples of the disclosure. As illustrated in FIG. 1A and FIG. 2, step 104 of providing one or more precursors can begin at a time t1. Optionally, one or more precursors can be provided to the reaction chamber at t1 or prior to t2. Thereafter, at t2, a continuous plasma is formed. The continuous plasma has a high RF component and a low RF component and is maintained throughout the duration of time period 206. At t3, a pulsed plasma is formed. The plasma is pulsed throughout time period 208. At t4, the power to form the plasma is reduced to extinguish the plasma.

During the period 208, the low RF plasma power can be pulsed, as illustrated in the enlarged portion of FIG. 2. A pulse can include a pulse on time 202 and a pulse off time 204, which can be repeated during period 208. During the period 208, the plasma may have an RF on duty cycle, or the percentage of the pulse on time 202 of a pulse (i.e. (pulse on time/(pulse on time+pulse off time))×100%). RF on duty cycle can be in the range of 25% to 75%, or between 40% to 60%.

In some examples, time period of the continuous plasma 206 can be in the range of about 4 seconds to about 14 seconds, between about 2 to about 20 seconds. In some examples, time period of the pulsed plasma 208 can be in the range of 10 seconds to 14 seconds. In some examples, a ratio of time of the time period of the continuous plasma 206 to the time period of the pulsed plasma 208 is in the range of about 1 to about 4. In the example depicted in FIG. 2, there is no intervening time period between time period 206 and time period 208. In other examples, there is an intervening time period. In the example depicted in FIG. 2, the reactant is flowed continuously throughout the time period 206 and time period 208. In other examples, the reactant does not flow throughout the time period 206 and time period 208.

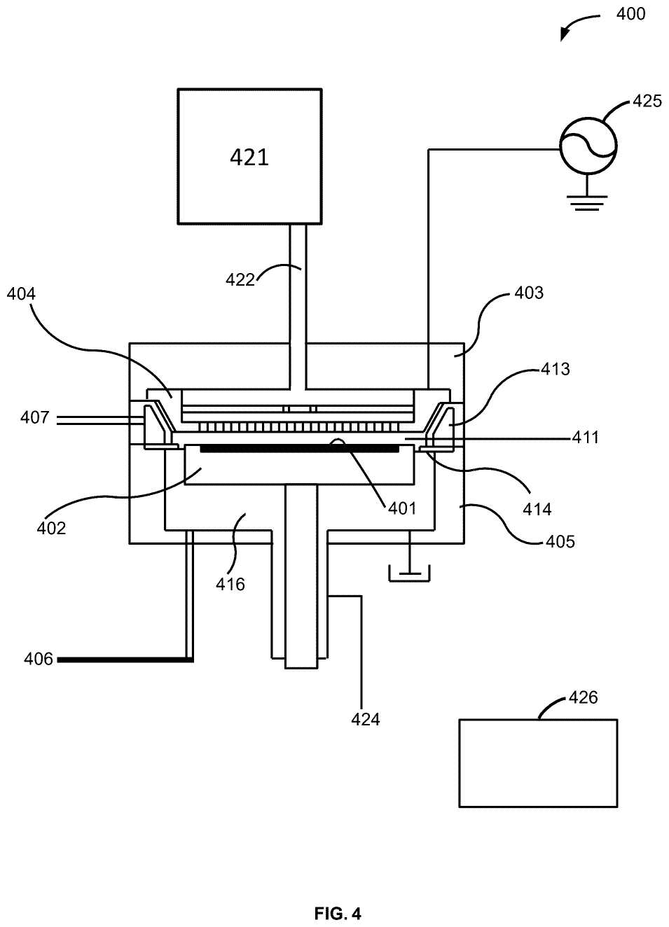

Turning now to FIG. 4, an apparatus 400 in accordance with exemplary embodiments of the disclosure is illustrated. Apparatus 400 can be used to perform one or more steps or sub steps as described herein and/or to form one or more films, structures or portions thereof as described herein.

Apparatus 400 includes a pair of electrically conductive flat-plate electrodes 404, 402 in parallel and facing each other in the interior 411 (reaction zone) of a reaction chamber 403. A plasma can be excited within reaction chamber 403 by applying, for example, high RF power (e.g., 13.56 MHz or 27 MHz) and/or low RF power from plasma generator 425, or power source, to one electrode (e.g., electrode 404) and electrically grounding the other electrode (e.g., electrode 402). A temperature regulator can be provided in a lower stage 402 (the lower electrode), and a temperature of a substrate 401 placed thereon can be kept at a desired temperature. A gas distribution system can be provided to deliver gas phase reactants and/or precursors to the interior 411 of reaction chamber 403. The gas distribution system can include a gas box 421 that may be a source for one or more gases, a gas transport line 422, and gas distribution device. Electrode 404 can serve as a gas distribution device, such as a shower plate. Reactant gas, dilution gas, if any, precursor gas, and/or the like can be introduced into reaction chamber 403 from the gas box 421 and through the electrode/shower plate 404. In reaction chamber 403, a circular duct 413 with an exhaust line 407 is provided, through which gas in the interior 411 of the reaction chamber 403 can be exhausted.

A skilled artisan will appreciate that the apparatus includes one or more controller(s) 426 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan. The controller 426 may be configured to enact a method for depositing films described herein. The controller 426 may be configured to enact the steps of: introducing at least one reactant into the reaction chamber; performing a hybrid dual frequency plasma cycle, wherein the hybrid dual frequency plasma cycle comprises: forming a continuous plasma for a first time period, and forming a pulsed plasma for a second time period.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing a film in a gap on a substrate, the method comprising:
providing a substrate, having a gap structure thereon, into a reaction chamber;
supplying at least one reactant into the reaction chamber; and
in the reaction chamber, performing a hybrid dual frequency plasma cycle, wherein the hybrid dual frequency plasma cycle comprises:
forming a continuous plasma for a first time period, and
forming a pulsed plasma for a second time period.

2. The method of claim 1, wherein the pulsed plasma is formed by pulsing a low RF power state during the second time period.

3. The method of claim 1, wherein the continuous plasma is formed by providing a continuous high RF power state and providing a continuous low RF power state during the first time period.

4. The method of claim 1, further comprising repeating the hybrid dual frequency plasma cycle in the reaction chamber until the film reaches a predetermined thickness.

5. The method of claim 1, wherein the at least one reactant is continuously supplied into the reaction chamber during the hybrid dual frequency plasma cycle.

6. The method of claim 1, wherein the ratio of the first time period to the second time period is in the range of 1 to 4.

7. The method of claim 1, wherein the RF on duty cycle % of the pulsed plasma is in the range of 25% to 75%.

8. The method of claim 3, wherein the power of the continuous high RF power state is in the range of 700 W to 1000 W.

9. The method of claim 1, wherein the first time period is in the range of 4 s to 14 s.

10. The method of claim 1, wherein the second time period is in the range of 10 s to 14 s.

11. The method of claim 1, wherein the second time period is subsequent to the first time period with no intervening time period.

12. The method of claim 1, wherein the gap structure comprising a bottom and a sidewall, and wherein the ratio of the thickness of the film deposited on the sidewall to the thickness of the film deposited on the bottom is between 2 and 3.

13. The method of claim 2, wherein the low RF power state of the pulsed plasma is in the range of 20 W to 100 W.

14. The method of claim 2, wherein the low RF power state of the pulsed plasma pulses between at least a first power state and a second power state, and wherein power delivered during the first power state is different from power delivered during the second power state.

15. The method of claim 14, wherein the power of the first power state is in the range of 60 W to 100 W, and the power of the second power state is in the range of 20 W to 60 W.

16. The method of claim 4, wherein a first iteration of forming a pulsed plasma is performed at a different pulse frequency than a second iteration of forming a pulsed plasma.

17. The method of claim 1, wherein the gap has a depth more than 160 nm.

18. An apparatus for depositing films on a substrate, the apparatus comprising:
a reaction chamber;
a gas distribution system for delivering gas phase reactants to the reaction chamber;
a plasma generator for providing a continuous plasma and a pulsed plasma to the reaction chamber; and
a controller operably connected to the gas distribution system and the plasma generator and comprising a program residing on non-transitory addressable storage medium, the controller configured to enact the following steps:
introducing at least one reactant into the reaction chamber;
performing a hybrid dual frequency plasma cycle, wherein the hybrid dual frequency plasma cycle comprises:
forming a continuous plasma for a first time period, and
forming a pulsed plasma for a second time period.

19. The method of claim 1, further comprising performing a post-deposition treatment comprising forming a dual frequency nitrogen plasma, wherein forming the dual frequency nitrogen plasma comprises providing a first RF power having a first RF frequency and a second RF power having a second RF frequency, wherein the first RF power is continuous, wherein the second RF power is pulsed, and wherein the first RF frequency is greater than the second RF frequency.

20. The method of claim 20, wherein a duty cycle of the second RF power is 50% or less.
